(19) United States
(12) Patent Application Publication
(10) Pub. No.: US 2010/0243437 A1
(43) Pub. Date: Sep. 30, 2010

(54) RESEARCH-SCALE, CADMIUM TELLURIDE (CDTE) DEVICE DEVELOPMENT PLATFORM

(75) Inventors: Timothy A. Gessert, Conifer, CO (US); Teresa M. Barnes, Energreen, CO (US)

Correspondence Address: PAUL J WHITE, Assoc. General Counsel;NATIONAL RENEWABLE ENERGY LABORATORY (NREL), 1617 COLE BOULEVARD, MS 1734, GOLDEN, CO, 80401-3393, US

(73) Assignee: Alliance for Sustainable Energy, LLC, Golden, CO (US)

(21) Appl. No.: 12/732,064

(22) Filed: Mar. 25, 2010

Related U.S. Application Data
(60) Provisional application No. 61/163,342, filed on Mar. 25, 2009.

(51) Int. Cl. C23C 14/34; C23C 16/44; C23C 16/00

(52) U.S. Cl. 204/298.09; 118/715; 118/725; 118/724

(57) ABSTRACT

An apparatus for dry deposition of thin films of cadmium telluride and other material layers required for a photovoltaic device. The apparatus includes a vacuum deposition chamber. A preheat station and source container are provided in the chamber, and the source container and material therein are heated to a deposition temperature. An integral shutter is placed in the chamber, and the shutter includes a planar body with a carrier receiver extending out from one end shaped as a two-prong fork or a closed loop. The shutter is positioned with the receiver and a received carrier in the preheat station and the body covering the source container outlet. The preheat station heats the carrier and sample to avoid thermal shock during deposition. The shutter is then positioned with the body moved from the source container outlet and the carrier receiver positioned to expose a sample surface to the deposition material.

### CROSS-REFERENCE TO RELATED APPLICATIONS

This application claims the benefit of U.S. Provisional Application No. 61/163,342 filed Mar. 25, 2009, which is incorporated herein by reference in its entirety.

### CONTRACTUAL ORIGIN

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

Cadmium telluride (CdTe) photovoltaics is a term that describes a photovoltaic (PV) technology that is generally based on the use of a CdTe thin-film absorber layer in a device that converts sunlight into electricity. There is a growing interest in the use of CdTe in solar cells and solar panels as CdTe thin films are one of the only thin films to surpass crystalline silicon PV technology in providing lower cost devices for the PV market including multi-megawatt systems. CdTe thin films are attractive in part because they can be deposited very rapidly upon a glass substrate to provide large PV panels (e.g., a panel with a width limited by a deposition tool but a length often only limited by structural concerns for the substrate) rather than being grown as single crystal devices.

In general, there is an ongoing demand for systems and methods that allow integration of processing, deposition, and analysis tools so as to facilitate studying of photovoltaic materials and devices such as new designs for PV devices. Specifically, as the CdTe industry grows, there is tremendous demand for knowledgeable staff and research scale tools to increase the understanding of this PV technology. There exist production scale deposition systems, and these typically involve feeding a continuous stream of products or substrate-based devices through deposition sources. For example, in a vacuum deposition setting (upward or downward deposition on a substrate), the products/substrates are fed in an end-to-end manner over an outlet for a deposition source such that the CdTe is blocked from floating/spraying upward and filling the deposition chamber by the deposition source materials themselves. Additionally, production scale systems typically are not designed for small batches or for supporting a dormant or idle period. Specifically, the CdTe source(s) typically is cooled completely between production runs and then warmed gradually to a desired temperature at the beginning of a next production run. A number of the initial products/substrates are defective as the deposition source is tuned the proper temperature and other deposition parameters are adjusted. Such a configuration is not well suited for smaller production runs such as a research-scale application in which it may be desirable to produce one sample or product/substrate device at a time (e.g., in a sequential manner).

Generally, there are no research scale CdTe deposition tools available for purchase, and tool manufacturing companies tend to avoid one-off type requests because it is difficult to make a profit on the first tool fabricated. Consequently, there is great need for the development of a relatively low cost research scale deposition tool that universities and other research entities could purchase and use to start or facilitate CdTe PV and other research requiring similar deposition of thin films. Such a tool would aid in workforce development and may significantly help advance CdTc technology development.

Presently, universities and other small research entities design and build research scale deposition equipment in-house. Very few entities and researchers have the expertise to adequately perform this task. Many research scale deposition tools utilize wet chemical (or simply, “wet”) processing as part of a conventional CdTe cell deposition process, and then switch (in some cases) to vacuum (or “dry) deposition. However, it is difficult in many cases to integrate wet chemical steps with vacuum deposition. For example, the wet part often must be completely dried and/or otherwise treated prior to a next deposition step. This can cause a delay, typically resulting in the sample/product having an improper temperature for a next step, may result in impurities being introduced, and/or irreproducibility of the final material/device performance (e.g., a sample/substrate device may be laid out to dry without protection from impurities in the air of the research lab).

The lack of deposition tools for use with CdTe and other materials limits the research entities in training students and/or workers to work in the CdTe industry (e.g., in the PV industry) and to advance the current state of the art in CdTe and other thin film devices. It also leads to relatively low quality research results based on poorly constructed devices from inadequate resources. Instead of spending ten or more years developing a mediocre CdTe deposition platform a properly designed/constructed research-scale, deposition system could allow a research entity to rapidly enter this part of the PV field for a much lower cost and with nearly immediate levels of competency and success in producing useful samples of product designs.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

It was recognized that it is desirable to provide a deposition cluster assembly (or deposition cluster tool/platform) that fits the existing gap between a high-end production-scale, deposition system and the present research-scale devices that are put together in a make-shift manner by researchers. The deposition cluster assemblies described herein are designed in part to meet a need in the CdTe industry to provide a platform that may use all dry or vacuum deposition processes (e.g., dry cadmium sulfide (CdS), dry cadmium chloride (CdCl₂), and the like as well as dry back contact processes) to make integration of the deposition processes (or modular deposition tools, deposition modules, or the like) easier and more manufacturable. In this manner, a university or other research entity may readily be able to provide budgetary resources for purchasing the deposition cluster assembly as a clustered tool with the individual deposition modules or modular deposition tools being linked together by a vacuum transfer chamber and various transfer mechanisms moving within this transfer chamber, including automated or manually operated robotic sample moving devices/assemblies, manual transfer arms/devices, and the like. In other cases, the research entity may purchase/use the modular deposition tools separately or in various subsets/arrangements. For example, an entity may utilize a close spaced sublimation (CSS) deposition tool or module by itself or with other deposition modules/tools so as to make use of its integral shutter and other features useful for supporting dry deposition of single samples or substrate devices (or products).

In some embodiments, a deposition cluster assembly is provided that facilitates rapid deposition of CdTe cells (e.g., CdTe-based samples/products/devices) without maintaining a continuous process as is the case for larger production-scale deposition processes. Such a deposition cluster assembly provides a much more flexible piece of equipment as it may readily be used in a research facility to produce one sample or substrate/superstrate product at a time. The deposition cluster assembly may also be configured to support “all-dry” CdTe cell deposition processes, e.g., deposition performed wholly within a vacuum environment. In contrast, most cell manufacturing techniques use several wet chemical processing/deposition steps, which can be difficult to integrate into a manufacturing process. The deposition cluster assembly (and fabrication methods provided by the assembly) described herein provides research-scale entities such as universities, research laboratories, start-up companies, and materials suppliers to more easily acquire and use a commercially available tool to conduct research on CdTe and other devices and related materials to more rapidly advance the state-of-the-art in the PV and other industries.

An exemplary deposition cluster assembly may be configured to deposit all of the layers in a complete CdTe photovoltaic device starting from either bare glass or a transparent conducting oxide (TCO)-coated glass substrate (i.e., a base substrate that may be a sheet or layer of glass), and, in this regard, temperature controls are provided throughout the cluster assembly to avoid rapid cooling or heating of the substrate. The deposition cluster assembly may accommodate differing types of glass for the substrate such as soda-lime glass, which is a present industry standard substrate for CdTe-based PV devices. Other types of coated or uncoated glass substrates (planar or curved/arched substrates) may be employed including borosilicate glasses (e.g., technical glasses), low-iron soda lime glasses, and the like. Additionally, the use of non-glass materials for substrate or superstrate materials can be considered.

Soda-lime and other glass substrates may be inherently difficult to handle or use in high temperature deposition environments because many glass substrates have very poor resistance to thermal shock. Subsystems within the cluster tool address this problem and prevent thermal shock over a preset limit suited to the particular glass substrate, but it should be remembered that thermal management of a glass substrate in a deposition process often presents some of the more difficult engineering challenges in designing a deposition tool or process. With this in mind, in embodiments of the deposition cluster assembly, the sample transfer chamber and modular deposition tools may be configured to maintain the sample/product temperature within a desired range to accommodate less than about 50° C. of thermal shock exposure such as by providing a heated transfer fork that maintains a sample/substrate carrier at a desired temperature during transfers and by providing preheater/heating and/or cooler/cooling stations in one or more of the modular deposition tools. Uncoated glass products (e.g., borosilicate, low-Fe glass, and the like) have low infrared (IR) absorption and are often difficult to heat, and, hence, some embodiments utilize a TCO coated glass substrate to assist in IR heating of the substrate such as in a preheating station.

The deposition cluster assembly may serve several purposes within the CdTe or PV industry. The deposition cluster assembly provides the ability to quickly fabricate complete CdTe devices. The deposition cluster assembly may be configured to accomplish the entire deposition process (excluding, in some cases, TCO deposition) in less than about 2 hours with a tool startup and shutdown time of less than about 30 minutes each (e.g., each deposition module may be dormancy tolerant such that little or no startup time is required as deposition sources may be maintained at idle/dormant temperatures at or near deposition temperatures). The deposition cluster assembly may be used to produce PV devices with relatively high conversion efficiencies such as initial conversion efficiencies of 10 to 12 percent, with it being likely that significant efficiency improvements may be produced after relatively modest investment in process development work (e.g., adjusting of a sample/product deposition and/or production recipe).

In many embodiments, the deposition cluster assembly includes a sample or product transfer chamber with one or more robotic devices (or robots) or with manual devices (such as transfer arms) for use in selectively positioning a sample/product. A load lock may be connected to the transfer chamber to allow samples/products to be initially loaded into the assembly and to later be removed when fully fabricated (e.g., all layers deposited upon the substrate). The transfer chamber may be maintained at vacuum, and the transfer fork may be heated to maintain a temperature of a carrier and a sample/product in the carrier or even to heat the carrier and sample/product to a desired temperature range. The deposition cluster assembly further includes one or more modular deposition tools (or deposition modules) to provide the various steps of a deposition process (e.g., to provide layers of a superstrate or substrated PV device), and each modular deposition tool is connected, via a valve/gate, to the transfer chamber such that the transfer robot (or manual device) may be operated to selectively position the sample/product in each modular deposition tool. Typically, the deposition cluster assembly includes at least a modular deposition tool configured for providing a CSS CdTe tool to effectively deposit a CdTe thin film on a glass substrate. The cluster assembly may also include other modules to form a PV device such as a window layer/front contact sputtering chamber/tool, a CdCl₂ deposition tool, a back contact sputtering chamber/tool, and/or a CVD TCO tool.

The deposition cluster assembly may be expanded by additional process modules or tools such as by addition of an analysis tool, addition of a CVD TCO tool or the like. The deposition cluster assembly of some embodiments is capable of depositing uniformly (i.e., plus or minus 5 percent) over a planar substrate (e.g., a glass substrate of nearly any shape and/or size such as a 6-inch square substrate to suit some existing analysis devices such as those used with silicon-based PV devices). A typical embodiment of a deposition cluster assembly may be able to support approximately six to twelve deposition runs per day, and the capability to deposit at least about one hundred deposition runs between major servicing shutdowns. In some embodiments, the load lock may be configured to hold a number of substrate/sample/product carriers or cassettes (such as 2 to 10 or more). The deposition cluster assembly may provide pre-heating of substrates/samples in the load lock module, which may be advantageous for some processing conditions, and, in other cases, pre-heating is provided by the transfer fork as well as in a loading/unloading station or position of a deposition or processing module/tool of the cluster assembly.

Unlike a commercial manufacturing system, the cluster assembly does not always have to operate in a sequential inline mariner and may be operated according to a recipe driven or “out-of-sequence,” backward sequence, or step-skipping mode (e.g., do not have to process every sample/product through each cluster module/tool in the same order but, instead, can set a recipe/script for use of the modules/tools to create a particular sample/product with a desired layer or component ordering). The deposition cluster assembly may sit dormant for relatively long periods of time (e.g., 12 hours to a day or more), and, therefore, the cluster assembly is typically configured to shut down in a dormancy tolerant mode, which may, for example, include maintaining deposition sources within idle/dormant temperature ranges to avoid source contamination or long heat up time requirements at startup.

One particular example, a thin film deposition apparatus is provided that may be used as one of the modular tools or chambers of a deposition cluster tool. The apparatus includes a deposition chamber and a source container for containing deposition material (e.g., a graphite boat for holding a quantity of CdTe or the like), and the source container includes an outlet into the deposition chamber such as an upward facing rectangular opening for releasing deposition particles upward into the chamber. The source container may also be designed to facilitate studies to test different sources that may contain different impurities or other properties. In these cases, the allowance would be made to remove sources easily from the source container. The apparatus further includes a shutter assembly (or integral shutter) that has a planar shutter body and a sample carrier receiver extending from an end of the shutter body. The carrier receiver (or fork, loop, frame, or the like) is configured for receiving a sample carrier and includes an opening for exposing a surface of a sample positioned in the received sample carrier (such as a rectangular opening for exposing a glass substrate or the like). The shutter assembly is selectively positionable (in an automated or manual manner) within the deposition chamber to first cover the outlet of the source container with the shutter body and to second position the received sample carrier over the outlet of the source container with the sample surface exposed to the deposition material through the opening in the carrier receiver.

The thin film deposition apparatus may also include a preheat station in the deposition chamber adjacent to the source container. In such a case, the shutter assembly may be configured for concurrently positioning the received sample carrier in the preheat station during the first positioning but with the shutter body covering the outlet of the source container, whereby the heated deposition material is retained within the source container. The apparatus may include a source heater for heating the deposition material in the source container to a deposition temperature, and the preheat station may include at least one heater for, during the first positioning, heating the sample in the sample carrier to a preheat temperature within about 50° C. of the deposition temperature (e.g., to avoid thermal shock of the sample substrate). The sample may include a soda-lime or other glass substrate, the deposition material may include cadmium telluride, and the deposition temperature is at least about 500° C. (e.g., the preheat may be up to 450° C. or the like).

In some cases, the apparatus may include at least one shutter heater positioned in the deposition chamber that is operable to heat the shutter body to a temperature of at least about a temperature of the source container. Further, to better seal in the deposition material during deposition, the sample carrier receiver may include sidewalls (with or without a sealing lip) forming a closed loop for receiving the sample carrier and defining the opening for exposing the surface of the sample. Then, the sidewalls may be positioned proximate to (and about an entire periphery of) an upper edge of the source container during the second positioning of the shutter assembly. Still further, the apparatus may include a load and unload chamber (which in turn may be connected to a robotic sample transfer chamber) connected to the deposition chamber via an access valve. The load and unload chamber may be configured for receiving the sample carrier and preheating the sample to an initial preheat temperature. The load/unload chamber can also act as a load-lock if the system is designed or operated without the robot (i.e., standalone operation). Also, the shutter assembly may be selectively positionable with the sample carrier receiver within the load and unload chamber to retrieve the sample carrier. The shutter body extends over the outlet of the source container during the retrieval of the sample carrier (and, later, during unloading).

In addition to the exemplary aspects and embodiments described above, further aspects and embodiments will become apparent by reference to the drawings and by study of the following descriptions.

### BRIEF DESCRIPTION OF THE DETAILED DRAWINGS

Exemplary embodiments are illustrated in referenced figures of the drawings. It is intended that the embodiments and figures disclosed herein are to be considered illustrative rather than limiting.

FIG. 1 illustrates a functional block, top view of an exemplary embodiment of a deposition cluster assembly or tool, showing internal components/subsystems of the deposition cluster assembly including preheating stations, deposition and sputtering stations, and an integral shutter for selectively exposing a sample, a superstrate, or a substrate device to a deposition source (e.g., a CdTe source heated to a temperature within a deposition temperature range);

FIG. 2 illustrates a top view (in function form with a top wall/cover removed) showing another embodiment of a deposition cluster tool or assembly that may be used to provide a smaller form factor cluster and/or to provide one in which fully or partially manual positioning of the samples/carriers may be performed;

FIGS. 3A-3C illustrate a top sectional view of a deposition tool (e.g., a tool configured for used in deposition of a CdTe thin film) using an integral shutter to selectively expose a source and using multi-step sequence (two or more steps) to provide thermal management (i.e., avoid thermal shock of glass substrate of sample);

FIG. 4 illustrates an end view of the chamber of tool/module of FIGS. 3A-3B showing more details of a source station with a sample and carrier positioned by the integral shutter over the source;

FIG. 5 illustrates in simplified form a sample or PV device that may be fabricated using a deposition cluster assembly or tool described herein with all dry deposition/processing;

FIG. 6 illustrates process flow of fabrication of a sample, a superstrate, or a substrate PV device, such as that shown in FIG. 5 by operation of the cluster assembly of FIG. 1; and

FIGS. 7A-7D illustrate a perspective, partial view of a module or tool that may be used in a cluster assembly such as to provide the CSS tool for providing CdTe thin films and/or for post-deposition processing of such a thin film.

### DESCRIPTION

The following description is directed generally to deposition cluster tools or assemblies that are designed to support an all dry (i.e., non-wet chemical) processing to fabricate samples or products (such as samples of PV materials or devices) that may be superstrate devices (wherein glass or other material acts as both the supporting structure and transparent window) or substrate devices (wherein light does not enter through a transparent supporting structure). A deposition cluster assembly as described herein may be clustered in the sense that a central sample-handling robot(s) may be provided under vacuum (e.g., high or ultra high vacuum) in a transfer chamber and one or more deposition and/or processing tools are interface with the transfer chamber. A load lock is also provided on the transfer chamber that can be used to insert and remove samples, and the sample-handling robot(s) acts to transport the sample(s) between the deposition and/or processing tools which may themselves be robotic to move the received samples and may be under vacuum. The modular deposition/processing tools also support thermal management to enable deposition on superstrates or substrates such as with pre-heating and cooling stations and through use of heated transfer forks (in the tools and/or on the robotic transfer arms). Significantly, at least one modular tool includes an integral source shutter that acts to receive and position a sample within the deposition chamber, preheat and post cool sample, as well to selectively expose the deposition source to cause the sample to deposit a layer of material (such as CdTe) on the sample substrate. These and other aspects of the deposition cluster assembly will become apparent from the following description with reference to the attached figures.

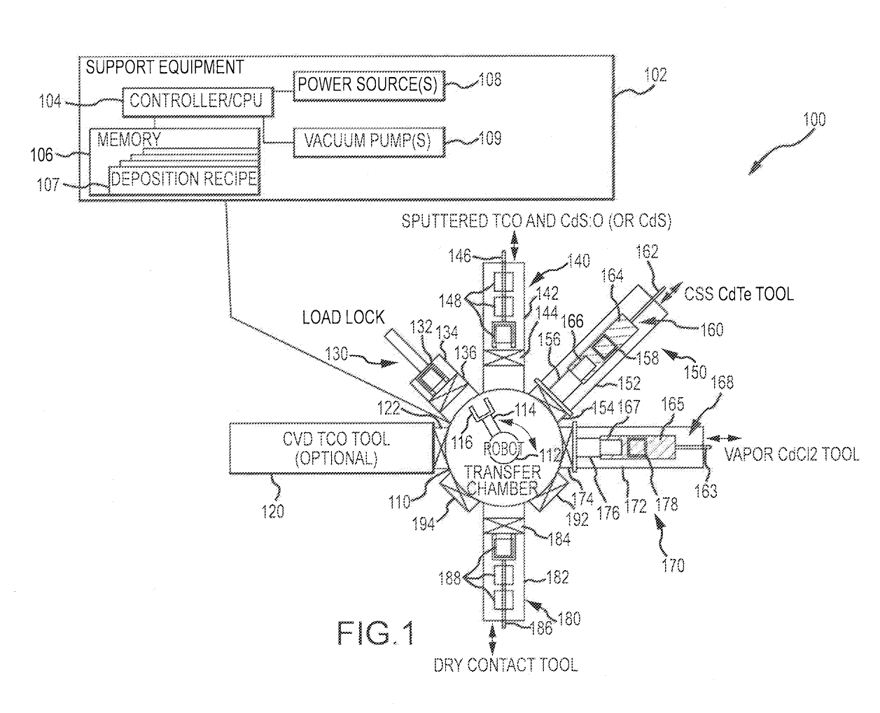

FIG. 1 illustrates with a functional block diagram a representative deposition cluster assembly 100. As shown, support equipment or a support system 102 is provided that may include a controller 104 (such as a processor and/or software run by such a processor along with a monitor for displaying information to an operator along with user input/output (I/O) devices for entering user or operator data such as selection of a deposition script or recipe, such as starting a deposition run, and so on), and the controller 104 may manage memory or data storage 106 that stores one or more deposition recipe 107 for use in defining a deposition/processing process performed on one or more samples in the deposition cluster assembly 100. The support equipment 102 may also include one or more power sources 108 (e.g., power sources for vacuum pumps, for heaters, for robotic transfer devices, and the like), one or more control units for pressure measurement, gas flow control, or other instruments as well as one or more vacuum pumps 109 for maintaining the transfer and deposition/processing chambers in the assembly 100 at vacuum.

As illustrated, the cluster assembly 100 includes a transfer chamber 110 that may be maintained at vacuum, and the transfer chamber may include a sample transfer robot 112 with one or more arms 114 that can be extended outward into the deposition/processing modules or tools as well as load lock 130 to retrieve and place/position a sample carrier (not shown). A fork 116 may be provided on the end of the arm 114 to mate with the sample carrier, and, in some embodiments, the fork 116 may be heated to provide thermal management of samples within the assembly 100. The transfer chamber 110 may include up to 8 ports as shown or more, and each of these ports may be used to mate with or receive a deposition/processing module or tool or be left open as shown with ports 192, 194 for expansion (e.g., for receiving an analysis tool, for receiving a transfer pod, or the like). The transfer chamber 110 may be considered “high vacuum” (HV) or may be ultra-high vacuum (UHV). In the HV application, the chamber 110 and, in some cases, the attached modules or tools may be capable of a base pressure in the range of about 1 to 5×100⁻⁸ Ton.

In the exemplary embodiment, the deposition cluster assembly 100 is adapted to form a PV device upon a received glass substrate. Specifically, the assembly 100 includes a load lock 130 sealably attached at a port or valve 136 of the sample transfer chamber 110. The load lock 130 includes a chamber 134 and a loading/positioning fork 132. The fork 132 may be adapted to receive a carrier and a glass substrate upon the carrier, which may be termed a platen in this description. After loading a carrier and sample into the chamber 134 on fork 132, the chamber 134 may be drawn down to vacuum or high vacuum, and the fork 132 (or included heaters) may be used to preheat the carrier and contained sample/glass substrate. The load lock chamber 134 may be configured to provide a load lock cassette that can concurrently accommodate/receive a number (such as 1 to 6 or more) of carriers with substrates. The load lock chamber 134 may also be provided with heaters and/or use fork 132 to heat the substrates/samples to a desired initial preheat temperature (e.g., up to about 150° C. or the like in some applications) and/or to cool the substrates (e.g., from about 400° C. to about 150° C. or less).

Note, the load lock 130 and modules/tools may have a similar or identical mating flange (such as component 136) to support modularity, reconfiguration, and proper attachment to the chamber 110 and access by sample transfer robot 112 (e.g., to provide a consistent reach distance from the center of the robot 112). Typically, the carriers and substrates/sample bases will have consistent sizes/shapes, too. For example, but not meant as a limitation, the carriers may be rectangular metal frames (to support temperature changes and to facilitate heat transfer to and from the substrate) that may be 7 by 7 inches (or any other useful shape/dimensions and the substrate/sample bases may be a similar shape but somewhat smaller (e.g., rectangular plate that is 6 by 6 inches in this particular non-limiting example).

The deposition cluster assembly 100 also includes a chemical vapor deposition (CVD) tool 120 linked to the chamber 110 at flange/valve 122. This tool 120 is shown as optional because the glass substrate may be provided with a TCO or other conducting film/treatment. However, in this example assembly 100, a glass substrate and carrier would be moved by the robot 112 from the load lock 130 to the CVD TCO tool 120 using fork 116 and robot arm 114. The tool 120 provides chemical vapor deposition of a transparent conducting oxide film on an exposed (lower or upper) surface of the substrate/sample.

The cluster assembly 100 further includes a tool 140 for providing a front contact/window layer on the sample. The tool 140 may be a sputtered CdS:O tool, or a sputtered TCO and/or buffer-coating tool, and, to this end, the tool 140 may include a chamber 142 that can be maintained at vacuum and a flange/valve 144 for mating the chamber 142 to the sample transfer (or robotic) chamber 110. The tool 140 may be a sputter tool that can deposit CdS, TCOs, buffer layers, or other materials. TCOs may be the front contacts of a device or sample while the CdS typically is used as or referred to as the window layer of the device or sample. A sample positioning arm 146 with a fork for mating with the carrier is provided in the chamber 142 and a number of sputtering stations 148 may be provided to selectively expose the sample to one, two, and/or three (or more) sputtering processes (e.g., by moving the sample via the positioning arm 146 over openings/outlets of each sputtering station 148. In some embodiments, the sample exiting the tool 140 has a front contact/window layer over the glass substrate (which may have been coated first in tool 120 with a TCO/buffer layer).

The deposition cluster assembly 100 also includes a tool 150 that is adapted to support deposition of CdTe thin films. The tool 150 includes a chamber 152 that, again, may be drawn down to or maintained at vacuum or HV and is flanged/valved 154 to sample transfer chamber 110. The chamber 152 may include one or (as shown) two pre-heating stations 156 that may be used to pre-heat a sample to a temperature that better supports deposition of a thin film of CdTe. To avoid thermal shock, it may be desirable to perform the pre-heating in two (or more) steps such as heat to 150° C. (from about 25 to 50° C. to about 150° C.) and then to second heat the sample to a deposition temperature for the glass substrate (e.g., from about 150° C. to a temperature in the range of about 300° C. to about 450° C.). The tool 150 also includes a CdTe deposition source 158 with a deposition opening or outlet to the chamber 152 such as an opening with a size and shape matching the substrate/sample (e.g., the same size and shape or slightly smaller such as a 6 by 6 inch square opening when this is the size and shape of the substrate). The substrate/assembly may be heated to a much higher temperature for deposition when it moves to the next station (note these steps/stations may be used for cooling after deposition).

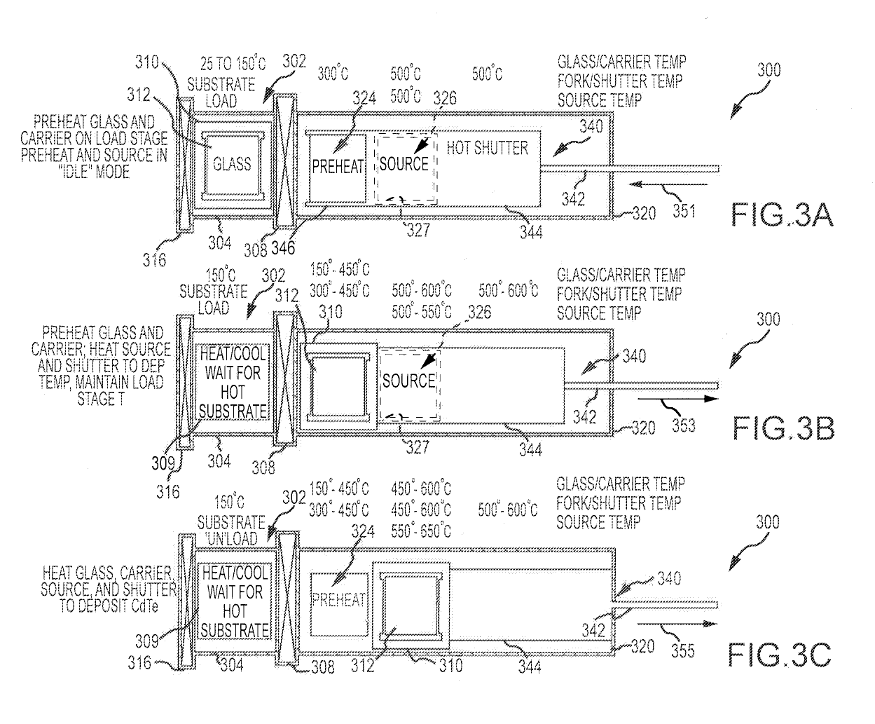

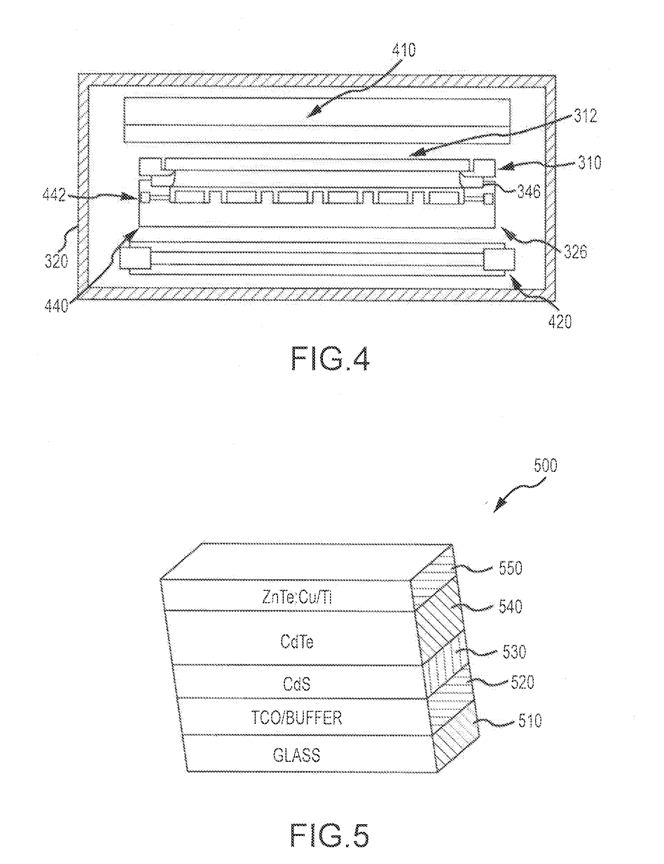

The tool 150 (which is explained in more detail below with reference to FIGS. 3 and 4) includes an integral shutter 160 that is used both to selectively position a carrier and sample/substrate in the chamber 152 and also as a retractable shutter/plug to the deposition source 158. To this end, the integral shutter 160 includes an arm 162 for linear moving a planar shutter body 164 within the chamber 152. A fork 166 is provided at the end of the body 164 for mating with the sample carrier, and the fork 166 is open (as is the carrier) such that the substrate and/or layers on the substrate (i.e., the sample) are exposed first to heating stations 156 and then to the deposition source 158. While the sample/carrier and fork 166 are positioned over heaters or pre-heating stations 156, the planar shutter body 164 acts as a shield or blocking component that plugs the opening to the source 158 such that the heated deposition materials do not escape and fill the deposition chamber 152 (as would be the case were it not for the presence of the body 164). When the body 164 is retracted further into the chamber 152 (or further outward), the fork 166 and a received carrier/sample are positioned over the opening/outlet to the deposition source 158 such that a layer of CdTe or other material from source 158 are deposited onto the substrate and/or other previously deposited sample layers. In some embodiments, the tool 150 is configured as a close spaced sublimation (CSS) CdTe tool to provide a deposition of CdTe thin film materials on a sample positioned with the integral shutter 160 over the source 158.

The deposition cluster tool or assembly 100 also includes a post-deposition treatment/processing tool 170. In the illustrated embodiment, the tool 170 may be a vapor CdCl₂ tool that is configured similarly to the tool 150 with a chamber 172 that is kept at vacuum and that is in communication via valve/flange 174 with sample transfer chamber 110. The chamber may include one, two (as shown), or more sample heating or pre-heat stations 176 to adjust the temperature of a sample in a stepwise manner. The chamber 172 may also include a source 178 for treating/annealing the sample such as a CdCl2 source. An integral shutter 161 is provided that includes an arm 163 (such as a threaded rod) for selectively and accurately positioning a planar shutter body 165 and a fork 167 within the chamber 172. For example, the rod/arm 163 may be moved linearly to position the body 165 over the opening to treatment source 178 and to position the fork with a carrier/sample over the heater stations 176. Then, after the sample is heated to a desired temperature, the arm 163 may be moved further to move the planar body 165 away from the opening of the source 178 and to place the sample over the source 178 to affect a desired treatment (such as post-deposition treatment and annealing of the CdTe thin film applied in tool 150).

The deposition cluster assembly 100 also may include a dry contact tool 188 that is linked to the sample transfer chamber 110 via flange/valve 184. The dry contact tool 188 may include a chamber 182 similar to that used for chamber 142 and may include a positioning arm 186 with a fork for mating with the sample carrier. The tool 180 may include one to three stations 188 for providing back contact processing and deposition in a dry manner (e.g., with the chamber 182 at HV and in a non-wet chemical manner).

The robot 112 may take many forms to practice the assembly 100 and to provide the sample transfer functionality. For example, the robot 112 may be configured to have sufficient XYZ motion to place a substrate/sample and a corresponding carrier into each deposition tool 120, 140, 150, 170, and 180 as well as load lock 130. The robot 112 also may be selected to be able to move relatively heavy carriers/samples through its full range of motion in chamber 110 (e.g., a heavy platen of a metal such as molybdenum may weigh up to 5 pounds or more for relatively small configurations such as 7 by 7 inch frame whereas larger samples and carriers may require a stronger robot 112, arm 114, and fork 116 arrangement).

To facilitate moving the modules or individual tools, a frame may be provided to support the vacuum chambers 142, 152, 172, 182 and so on that rest on large diameter, height-adjustable casters or the like. When the tools/modules are connected to the transfer chamber 110, the tools/modules may be supported on leveling pads attached to such a frame. Non-magnetic and HV-compatible construction techniques and materials may be used throughout the assembly 100. All the tools/modules (with the possible exception of the CVD TCO tool) may be configured for upward deposition (onto a superstrate with the sample facing downward in its carrier). The CVD TCO tool 120 or robot 112 may be adapted to be able to flip the substrate when transferring into and/or out of the tool 120 (e.g., if the CVD TCO tool 120 is not provided in a “deposit up” configuration).

Deposition uniformity in the tool 150 and/or other tools may be about plus/minus 5 percent except for about 0.5 centimeters from the edge of the carrier, and tools/modules in the assembly 100 may be equipped with the proper size deposition sources (or outlets into the vacuum chambers) to achieve such uniform deposition on the samples. The pumps of the support equipment 102 may be compatible with oxygen service, and dry pumps may be used. Pressure in the assembly 100 may be measured by a high-stability ion gauge for base pressure measurement. High-precision, temperature-compensated capacitance manometers (about 100 mTorr full scale) may be used for pressure measured during sputtering. Thermocouple or Pirani gauges may be used for interlock control. Viewports may be provided in the chambers of the assembly 100 to allow monitoring of deposition in one or more of the chambers/tools. Other ports may be used to allow for in-situ process control and monitoring on one or more of the deposition/processing chambers. Extra-ports 192, 194 may be provided for future modifications/additions to the assembly 100.

In some embodiments, the module/tool 140 is a tool for providing deposition and/or sputtering of a front contact/window layer tool. In some embodiments, the assembly 100 is used to form samples of PV devices, and, in some of these embodiments, the tool 140 may be used to provide deposition of a TCO and window layer (e.g., a layer of CdS or the like). The tool 140 may be nominally identical to the dry contact tool 180 that may be used/operated to provide a dry back contact with a sputter deposition chamber (although these tools do not have to be identical in configuration to practice the assembly 100). The tool 140 may include large linear cathodes at sputter stations 148 to yield uniform deposition at high rates. The module/tool 140 may be used initially to sputter CdS, CdS:O, or other window layers, and it may also be used to sputter various transparent front contacts on a glass substrate of a sample on a carrier placed into chamber 142 and positioned relative to stations 148 with arm 146.

In one embodiment, the chamber 142 may include 3, 4, or more source positions 148, and these may provide CdS:O sputter deposition such as at a rate of at least about 20 nm/minute. Three cathodes may be supplied to provide radio frequency (RF), direct current (DC), or pulsed DC compatible deposition. Minimum source-substrate distances may be employed to improve source usage. Removable shielding to capture deposit “over spray” and automated shutters may be utilized in tool 140 on one or more of the sources at stations 148. A substrate heater (not shown in FIG. 1) may be used to heat/pre-heat substrates of samples (e.g., bare glass substrates) to about 40° C. in a pure oxygen ambient prior to sputtering such as in an initial pre-heat station or during/prior to sputtering in chamber 142.

Substrate bias on the order of about 100 Watts (RF, 13.56 MHz) may be allowed/achievable in tool 140. Electronics and hardware provide the ability to run substrate bias in a sputter-etch mode while controlling contamination of the sources or substrate by plasma etched products (e.g., separate “etch-mode” location with sufficient source shutters). Appropriate dark space shielding may be provided for the substrate in the chamber 142. The chamber 142 may include an RF source such as a 1000 W, 13.56 MHz RF source with auto match and a 3-position, computer-controlled switch. Controls may be provided in support equipment 102 to run the RF source in either an RF power control mode or a DC self-bias control mode. The chamber 142 may contain a DC source such as a 1000 W DC source with a 3-position, computer-controlled switch. Further, in some cases, the chamber 142 may contain a pulsed DC source such as a 1000 W pulsed DC source with a 3-position, computer-controlled switch. Still further, an RF bias source may be provided such as a 100 W RF source. Other support equipment for the tool 140 may include four MFC channels (2-100 sccm, 2-10 sccm) with gas inlets to chamber 142 for Ar, N₂, O₂, and other process gases. The chamber 142 may also have an automated throttle valve to maintain sputter-etch mode pressures of about 5-20 mTorr and capability for downstream and/or upstream pressure control. Safety-oriented engineering controls may also be provided for tool 140 for containing toxic materials (e.g., cadmium). Note, tool 140 may be used to deposit window layers made up of a variety of materials and is not limited to those discussed above. For example, the window layers may be CdS or CdS:O but may also be CdSTe window layers or other useful materials.

In some embodiments, the tool 150 plays a key role in providing a research-scale cluster assembly 100. The tool 150 may take the form of a close spaced sublimation (CSS) CdTe tool that is used to provide deposition of CdTe thin film materials on a sample provided on a carrier that is positioned in the chamber 152 (and, in some cases, may be used to deposit CdS or other materials/layers in place of or in addition to the sputtering tool 140). The tool 150 may have a single CdTe sublimation source 158 with multiple substrate pre-heating stages (e.g., two or more) 156. The CdTe deposition rate with source 158 may be about 0.8 microns per minute or more with a total cycle time of about 25 to 45 minutes (e.g., about 35 minutes in one example) including substrate heating and cooling. The chamber 152 may be compatible with oxygen ambient (e.g., 20 percent oxygen in helium, argon, or nitrogen).

Substrate deposition temperatures when the fork 166 is positioned over the opening/outlet of source 158 may be on the order of about 450 to 600° C., and substrates or samples may be preheated on preheating stations 156 in a stepwise manner. Typical substrate deposition temperatures (e.g., of the sublimation source 158) may be on the order of about 550 to 650° C. (such as about 570° C.). The tool 150 provides thermal management with the preheating stations 156 to transfer samples with glass substrates/layers with integral shutter 160 without excessive thermal shock (e.g., less than about 50° C., which is a useful upper limit for many glasses used in CdTe-based PV technologies). The shutter body 165 may be heated, and the tool 150 may include heaters or other devices to heat the shutter or at least the fork 166 (and or portions of body 164 positioned over opening to source 158). Allowance may be provided for placing the source 158 into an idle or dormant mode such as by maintaining the temperature of the source 158 within an idle/dormancy temperature range (e.g., 450 to 550° C. or about 500° C. for many CdTe sublimation sources). The source 158 may be selected to be capable of about one hundred or more depositions of a desired deposition thickness (e.g., 10 μm thickness) without service/replacement. In some embodiments, the tool 140 is modified to take the form of a CSS tool similar to tool 150 but configured for CdS deposition.

The CSS source 158 may include the following components and/or functions: (a) allowance for additional gas input; (b) a POCO Fabmate graphite construction or similar material; (c) CdTe material in a non-powder form; (d) reconfigurable CdTe source pellets, chunks, pucks, or pieces in the source for uniformity; and (e) a molybdenum, Inconel®, and/or graphite shutter and carrier (e.g., component 160 may have a planar body 164 formed of such materials as may be the sample carrier or frame used to support the sample substrate throughout the deposition/processing in the cluster assembly 100). The chamber 152 may be adapted to provide a capability for downstream or upstream pressure control. Removable shields (not shown in FIG. 1) may be used where insufficient source-to-shutter sealing is expected to produce significant effluent.

The tool 170 may be included in the cluster assembly 100 to provide post-deposition treatment and annealing capabilities, and the tool 170 may take the form of a vapor CdCl₂ tool. The tool 170 may be configured similar to the CSS CdTe deposition tool 150 with similar structure and capabilities. As shown, the source 178 is provided with an opening that is shuttered selectively from the interior of the chamber 172 by the body 165 of the integral shutter, and the source 178 may be loaded with CdCl₂. Then, the tool 170 may be operated to provide a CdCl₂ treatment process as a post deposition treatment/anneal that may be desirable for providing a high quality CdTe layer on a PV device. The chamber 172 may be built to withstand Cl₂ exposure and be highly resistant to corrosion. The source 178 may be operated at a temperature in the range of about 425 to 475° C. (e.g., about 450° C.) with the sample/substrate temperature limited (typically) to about 550° C. such as by use of preheating station(s) 176 in tool 170. In some embodiments, the CdCl2 processing step provided by tool 170 is completed in about 5 to 10 minutes. Again, safety engineering controls for the use of toxic materials (e.g., cadmium) is provided in the design of tool 170.

Note, sample transfers may also be “hot.” For example, a sample may be passed to a hot fork at elevated temperatures (e.g., 150 to 500° C.) so as to allow the pre-heat/cooling step to be skipped in a next chamber so as to reduce cycle times. This may be particularly useful, for example, between the CdTe deposition and CdCl₂ processing steps, but such hot sample transfers with a hot fork on the sample transfer robot or other sample transfer device may be useful between other steps or processing tools/chambers.

The dry contact tool 180 of the cluster assembly 100 may be implemented to provide back contact processing and deposition. The structure and operation of the chamber 182 may be similar to that of the front contact/window layer sputter tool 140. The tool 180 may be adapted to perform at least the following four steps/functions: (a) dry preparation/etching of the CdTe layer (or thin film) surface; (b) back contact deposition (e.g., ZnTe or the like deposition at about 5000 A; (c) back contact metallization (e.g., about 1 μm), and (d) second back contact metallization. The back contact deposition (e.g., deposition of ZnTe) may be performed in one of the stations 188 at deposition rates on the order of 10 to 12 A/second (RF, DC, or pulsed DC). In this regard, large linear cathodes may be provided to affect ZnTe and/or metal depositions in the tool 180.

The optional CVD TCO tool may be provided for performing chemical vapor deposition of transparent conducting oxide thin films as an initial step to a glass substrate/sample provided in load lock 130. The tool 120 may be capable of using bare glass substrates with appropriate heating requirements for such substrates (e.g., to 600° C.). The CVD TCO tool 120 may also be configured for a “deposit up” configuration so that flipping is not necessary. A substrate carrier may be used during the CVD process in the tool 120. Since the carrier may be used in all other processes in assembly 100, accommodation may be provided for removing and replacing the substrate in the carrier. The CVD in tool 120 may be done in a hot mode (e.g., substrate heated to about 500° C. or the like), but provision may be made to start with a cold (or load lock 130 preheated) substrate, then hand-off to a low temperature process for window layer sputtering in tool 140.

Provision may also be made for preheating and substrate cooling in either the CVD chamber of tool 120 and/or on the robot fork 116. SnO₂:F is a standard TCO material and may be used in tool 120 in the deposition process to provide desired thickness rates (e.g., rates of about 5000 A in about 12 minutes or the like). Buffer layers may be made up of i-SnO₂ (e.g., with thickness deposition rates of about 2000 A in about 5 to 6 minutes or the like). The CVD TCO tool 120 may also be used to grow other binary and ternary metal-oxide TCOs. The tool 120 may be configured to provide for substrate temperatures in the range of about 400 to 600° C. Safety precautions may include interlocks and a run-vent manifold design. A showerhead configuration may be used in tool 120 to provide adequate substrate rotation to meet plus/minus 5 percent uniformity specifications. A metal-organic precursor delivery system may be used with tool 120 to provide for four liquid precursor sources: tetramethyltin, dimethylcadmium, and two additional sources. Liquid sources may be contained in a sealed argon atmosphere glovebox to facilitate bubbler changes. Provision may also be made for appropriate temperature, pressure, and gas flow control for controllable delivery of metal organic precursors in tool 120 (such as with support equipment 102). Gas delivery may be configured for four reactant gas sources (e.g., oxygen, fluorine, silane, and/or other reactant source gases). Other gases such as argon for the glove box supply and nitrogen for carrier and purge gas purposes may be provided with tool 120. Appropriate gas cabinets for the fluorine and silane may be self-closing, ventilated, sprinklered, and so on and may be provided within close proximity to the tool's chamber for a compact configuration. Gas manifolds incorporating standard safety features may be integrally connected to the tool's chamber.

All of the tools in the cluster assembly 100 and the robot 112 in transfer chamber 110 may be fully integrated to run from one software package run by controller/CPU 104. The tools and robot 112, for example, may be configured to run in a recipe-driven mode in which the controller 104 uses recipes for making layered samples based on deposition/processing recipes/scripts 107. Of course, multiple computers may be utilized to operate the cluster assembly 100 that may run one, two, or more software packages (e.g., each tool may use its own recipe or the like). In other cases, though, the controller may be operated in response to user input to operate in a non-sequential mode with a user instructing the assembly 100 to operate in a particular manner to form a sample. The tools may be equipped with sensors on their loading stage(s) that senses the presence of a substrate/carrier on their loading stage. The output of this sensor may be read/processed by controller to control operation/use of the loading stage and/or a tool of assembly 100 such that during automated transfers it is not possible to attempt to load more than one platen on a loading stage at a time, and the loading of a sample/carrier into a tool may trigger operation of that tool to perform a programmed processing/deposition sequence. The platen/loading stages or stations may include limit switches on all axes that prevent the stage from damage that might occur if the stage attempts to move out of its normal range of motion.

Automation of the cluster tool 100 may be accomplished by the control systems of support equipment 102 including controller 104, which cooperate to achieve both automated and manual operation of the tool 100. The cluster tool or assembly 100 may include a single computer system that controls the data acquisition, the robot 112, the loading stages of tools, and operation of the tools of the assembly 100. The control system (such as controller 104 and/or this single computer) may be configured to allow for automated deposition or annealing recipes 107 to be generated by a user. Recipe generation may be configured to involve selecting gas sources, targets, temperatures, deposition thicknesses/times, and/or other relevant parameters of the assembly 100 to define a fabrication process for a PV or other deposition-based device/product/sample. The control system may have the capability to export or import recipes 107 or deposition parameters for each run in easily readable text files.

Transfer of platens into and out of the various tools from a central sample-handling chamber 110 may be fully automated and under the control of the central sample-handling robot 112. To accomplish this, the tools of the assembly 100 may send/receive commands to and from a computer/controller 104 controlling the central robot 112. These commands inform the tools when to open or close the gate valves 122, 136, 144, 154, 174, 184 between the sample chamber 110 and the individual tool chambers 134, 142, 152, 172, 182 and chamber of tool 120 and also inform the tools where to move the receiving/loading stage to receive or unload a platen with a particular sample. Once a platen has been loaded into a tool, it is possible to perform either a fully automated deposition sequence via operation of the particular tool or a fully or partially manual deposition/processing on the sample.

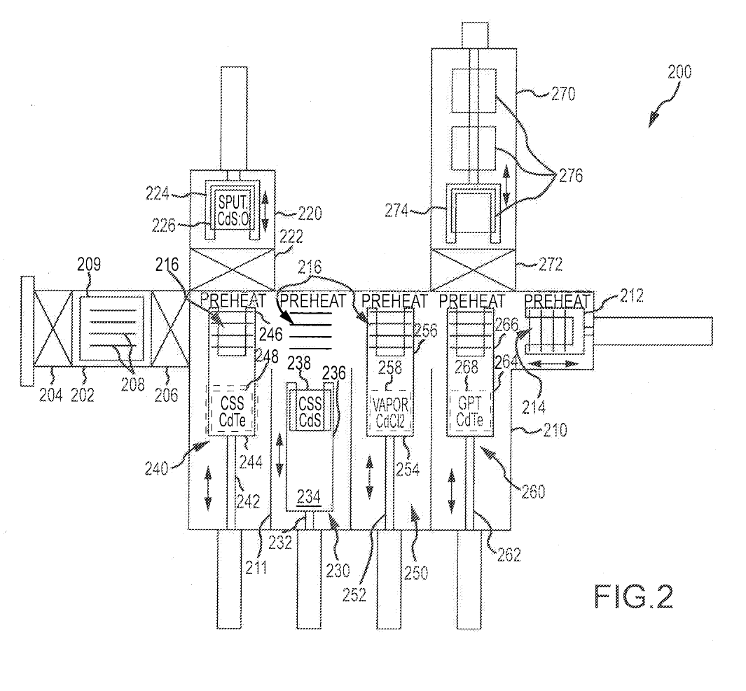

FIG. 2 illustrates another deposition cluster assembly 200 that may be utilized to provide a smaller form factor cluster (such as for many university settings). The assembly 200 may also be useful for providing a less expensive device as well as one that may be operated without a central sample handling robot (e.g., with linear positioning arms or the like). The assembly 200 is shown to include an active layer or central chamber 210 that may be operated at 50 mTorr to 20 Torr or the like (e.g., at HV) and with a number of deposition/processing tools/chambers separated by shields (e.g., temperature and material shields). A load lock 202 is provided to allow platens 209 (e.g., a carrier with a sample substrate) to be loaded via gate valves 204 into a preheat station where the substrates 209 may be preheated with heater 208. The load lock 202 may periodically/selectively be opened to the active layer chamber 210 via gate or chamber access valve 206 at which point a sample transfer arm with fork 212 may be extended across the chamber 210 to retrieve the sample/carrier 209. The load lock 204 may allow access by an analysis tool, a pod, a robot, or the like for loading and removal of samples/carriers 209 on a platen cassette. Upon removal from load lock 202, the fork 212 may be moved to position the sample 209 in a number of locations in the chamber 210 such as temporarily on a preheater 214 to raise the substrate temperature to (or maintain the temperature at) a desired processing/deposition temperature.

Next, the sample transfer arm/fork 212 may be moved in chamber 210 to place the sample on preheater 216 proximate to the front contact/window layer tool or chamber 220. After a period of time or when tool 220 is ready, the access valve 222 may be opened and the arm/fork 224 may be extended outward into the chamber 210 to retrieve the sample 209. The arm/fork 224 may then be positioned into the chamber 220 to place the sample 209 over the sputtering source 226 (e.g., a CdS:O source or the like) for sputtering of a front contact/window layer on the sample 209. After this is completed, the access valve 222 may be opened (closed during sputtering operations), and the arm 224 used manually to position the sample 209 on the preheater 216. The integral shutter 240 with the arm 242, planar body 244, and transfer fork 246 may then be used to retrieve the sample 209 and move the sample (once it is heated to a desired temperature by preheater 246) to be over the opening to a CSS CdTe source or other deposition source 248. As discussed earlier, the integral shutter 240 acts to block release of materials from the source 248 by blocking/shielding the opening/outlet of source 248 until the fork 246 carrying the sample 209 is placed over the opening of source 248. In this manner, the source 248 may be kept at or near a deposition temperature on an ongoing basis without release of materials into active layer chamber 210. When deposition is completed (e.g., deposition of a thin film of CdTe), the integral shutter 240 may be moved outward into the chamber 210 to place the sample 209 back upon the preheater 216.

The sample 209 may then be repositioned on another heater 216 by arm 212 and then undergo post-deposition treatment and/or annealing by using integral shutters 230, 250 to position the sample 209 over sources 238, 258 (e.g., a CSS CdS source, a vapor CdCl₂ source, or the like). Again, integral shutters 230, 250 are used both to block/contain the materials from being released by sources 238, 258 via their planar bodies 234, 254 that may extend over and abut the chamber 210 adjacent the openings to sources 238, 258 and also to retrieve sample 209 from preheaters 216 and then expose the sample 209 to sources 238, 258 by moving forks 236, 256 over openings/outlets of sources 238, 258.

The assembly 200 may also include additional processing stations such as a CdTe source 268 that is utilized by using the fork/arm 212 to reposition the sample 209 and then to use the integral shutter 260 with body 264 and fork 266 to position the sample 209 over the opening of source 268. Additionally, the assembly 200 may include a dry contact tool or chamber 270 mated to the active layer chamber 210 via access valve 272. The sample positioning arm 274 may be used to retrieve a sample 209 from the active layer chamber 210 via the valve 272 (which is closed after retrieval) and to selectively position the sample 209 over one or more sources 276 (sec discussion of tool 180 of FIG. 1 for one useful configuration of chamber/tool 270). Upon application of the dry contact with chamber 270, the valve 272 is opened and the fork/arm 274 is used to position the completed sample 209 back into the active layer chamber 210 where the arm/fork 212 may be used to move the sample 209 back into the load lock 202 for removal from the deposition cluster assembly 200.

As will be appreciated from the description of FIGS. 1 and 2, the use of an integral shutter within a deposition chamber facilitates selective exposure of a sample to a deposition source, which may be maintained at or near a deposition temperature. FIGS. 3A to 3C are useful for further describing use of such an integral shutter and also for explaining thermal management that may be provided in a deposition tool such as a module or tool that may be used as a CSS chamber for deposition of a thin film of CdTe. FIG. 3A illustrates a top sectional view of a deposition tool or module 300 that may be connected via an external load lock (or substrate/sample load and unload assembly) 302 to a sample transfer chamber and/or an active layer chamber (see cluster assemblies 100 and 200 of FIGS. 1 and 2, for example). The module 300 may be used for example as the tools/modules 150 and 170 shown in FIG. 1 (e.g., as a CSS CdTe tool and/or a vapor CdCl₂ tool or the like) by choice of sources 326 and/or control of other parameters such as temperatures obtained at preheating stations, deposition times, and the like.

The module/tool 300 includes a load/unload assembly (or external load lock) 302 connected to a deposition/processing chamber 320. The load/unload assembly 302 may include a chamber 304 in which one or more carriers 310 with samples 312 (e.g., glass substrates with one or more layers such as front windows or the like applied) may be received loaded. The load/unload assembly 302 includes a flange 306 for sealably attaching to another cluster chamber (not shown in FIG. 3A) such as sample transfer chamber as shown in FIG. 1. A gate valve 308 may be provided between the load/unload chamber 304 and the processing/deposition chamber 320 to allow the carrier 310 to be moved into and out of the chamber 320.

As shown in FIG. 3A, the carrier 310 with substrate 312 has been initially loaded and may be heated by one or more heaters 309. In other cases, the assembly 302 may be used to cool a substrate or sample 312 prior to it processing in chamber 320 and/or in a next module (e.g., before removal from the load/unload assembly 302, which may involve moving a substrate 312 and its carrier downward (or upward) in chamber 304 away from heater 309. In FIG. 3A, the chamber 320 is shown to include a source 326 with an opening 327 to the interior spaces of the chamber 320, and, in some cases, this may be a CSS CdTe source that may be heated to a deposition temperature. The chamber 320 also includes a preheater 324 that may be used to heat the sample 312 on carrier 310 to a deposition temperature.

Significantly, the chamber 320 also contains an integral shutter 340 that includes an arm 342, a planar body 344 and a fork 346 extending outward from the solid body 344. The body 344 may be positioned by linear movement 351, 353, 355 to cover the opening 327 to the source 326 as shown in FIGS. 3A and 3B. The fork 346 is used to capture/receive the carrier 310 (such as by mating with recessed surfaces or grooves in the frame defined by the carrier 310) so as to move or position the sample 312 in the chamber 320 and to selectively expose the sample 312 to a heater 324 and to the source 326 (e.g., the fork 346 may have two space-apart prongs or differently configured end-effector that expose the sample surfaces to components in the chamber 320 below and above the integral shutter 340). As a result of the combination of the solid, planar body 344 and the open fork 346 in the shutter 340, the movement of the body 344 away from the opening 327 and positioning of the fork 346 with a received carrier 310 over the opening 327 results in the sample 312 being exposed to the source 326 (e.g., results in selective deposition of material released through the opening 327 onto exposed surfaces of the sample or substrate 312).

In one embodiment, the tool or module 300 is used to provide a three step deposition using the source 326, which may be a CdTe sublimation source in some cases, so as to avoid thermal shock. As shown in FIG. 3A, a first step may involve the loading of a carrier 310 with a substrate/sample 312 (a glass substrate with or without other layers previously applied) into the load/unload chamber 304. In the first step shown, the substrate 312 and carrier 310 may be preheated on the load stage preheater, the valve 308 may be closed, the shutter 340 may be in a retracted position in which the body 344 covers the source opening 327, and the source 326 may be in an idle or dormant mode. In one embodiment, the substrate 312 from about 25 to about 150° C. while the preheater 324 is placed at about 300° C. and the source 326 is placed or retained at a dormancy/idle temperature of about 500° C. The position of the integral shutter 340 in the chamber 320 may result in the fork being heated to 300° C. and the body 344 being heated to about 500° C. (due to the heat of the source 326 and/or use of additional heaters above the body 344 not shown in FIG. 3A).

FIG. 3B illustrates a second step of the deposition process. In this step, the integral shutter 340 has been moved as shown at 351 in FIG. 3A to retrieve the carrier 310 from the load/unload chamber 304 via valve 308. The integral shutter 340 has then been moved as shown at 353 to the position of FIG. 3B such that the fork 346 and its received carrier 310 are positioned over in a preheat position/station such that the substrate 312 is adjacent over the preheater 324. In this position, the source opening 327 is covered by the planar body 344 of the shutter 340 such that no material escapes into the chamber 320. The temperature of the glass substrate of sample 312 may have been 150° C. (or another temperature) after completion of the first/initial preheating in load/unload chamber 304 and, the preheater 324 may be used to further raise the substrate of sample 312 temperature from 150 to 450° C. In the step/mode shown in FIG. 3B, the temperature of the fork 346 may also be raised to about 450° C. with the sample 312 and carrier 310. Also, in this second step of the deposition process, the source 326 may be heated from 500 to about 550° C. while the body 344 may also be heated from about 500° C. to about 600° C. (again with heaters (not shown) above the shutter 340 in chamber 320).

Once the sample 312 is adequately preheated to limit thermal shock to less than about 50° C. (useful for many glasses), the third step of the deposition process may be performed as shown in FIG. 3C. As shown, the arm 342 is moved at 355 to withdraw the body 344 from over the opening 327. This would result in deposition materials from the heated source 326 being released into the chamber 320 but for the movement on the fork 346 of the carrier 310 with sample 312. The positioning of the fork 346 adjacent/over the opening 327 causes the sample 312 to be exposed to the source 327 such that upward deposition onto the sample 312 occurs and materials are not released into the chamber 320. In the step shown in FIG. 3C, the source 326 may be heated to a deposition temperature such as from 550 up to 650° C. and the sample 312 may have its temperature raised from 450 up to 600° C. Upon completion of deposition (such as deposition of a thin film of CdTe), the shutter 340 may be moved toward the unload/load chamber 304, the gate opened 308, and the sample 312 and carrier 310 placed in the load station (for cooling and then removal from tool 300).

In summary, FIGS. 3A to 3C show a schematic that may be used for a CSS chamber with a basic operating sequence of: (1) loading a substrate and carrier onto a heated stage while the shuttered source is a “idle”; (2) preheating the substrate and carrier while heating the shuttered source up to a deposition temperature; and (3) deposition. This approach incorporates a heated integral shutter, which enables preheating and deposition without opening the CSS source to the chamber. The “substrate load” assembly may function as a single or multiple sample heated load lock with differential pumping and pressure measurement.

FIG. 4 illustrates a sectional end view of the chamber 320 of tool 300 with the shutter 340 in the position shown in FIG. 3A, i.e., with the sample over the source 326. In FIG. 4, the source 326 is shown to include a heater 420 such as IR lamps for heating the source 326 to keep it at an idle temperature (e.g., 500° C. or the like depending on the source materials) and then to heat it up to a deposition temperature (e.g., 550 to 650° C. or the like). The source 326 may include a hearth 440 (e.g., a Fabmate Graphite hearth, a pyrolytic graphite-coated Poco graphite hearth, or the like depending on whether the source is a pressed or loose source). The source 326 may also include secondary source injection ports 442. FIG. 4 illustrates that the fork prongs 346 provide a seal about the edge for the opening to the source 326 and the fork 346 provides an opening from the source 326 to the substrate (e.g., a soda-lime glass substrate or the like) while blocking material from being deposited upon the carrier 310. Above the substrate 312 (which is positioned face or top downward toward the source 326), the chamber 320 includes a top heater 410 that functions to heat the substrate 312 further to a deposition temperature such as 450 to 600° C. or the like.

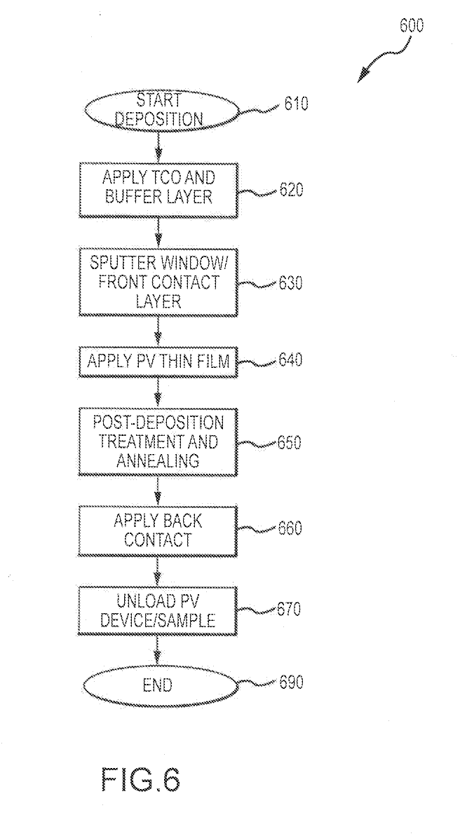

FIG. 5 illustrates a PV sample or device 500 that may be formed by operation of the deposition cluster assembly 100 of FIG. 1, and FIG. 6 illustrates simplified flow of the operations of the assembly 100 to produce the device 500. As shown, the deposition may be started at 610 such as by providing a recipe 107 to the assembly 100 and placing the tools 150, 170 in idle mode (e.g., with the sources 158, 178 heated to idle/dormant temperatures). Also at 610, a substrate 510 such as a sheet or piece of soda-lime glass may be provided and positioned within the load lock 130 in chamber 134 on fork 132. In the load lock 130, the substrate 510 may be preheated such as to 25 to 50° C. or the like. At 620, the substrate 510 may be transferred such as via operation of robot 112 in conjunction with valves 136, 122 to transfer the substrate 510 (in a carrier) to a CVD TCO tool 120. Further, at 620, the tool 120 is operated to apply such as via CVD or sputtering a TCO and buffer layer 520 onto the substrate 510.

At 630 of method 600, the sample in its carrier are then transferred by the robot 112 (and by operation of valves 122, 144) to tool 140 configured for depositing a front contact/window on the device 500. In some cases, the window layer 530 is sputtered as a layer of CdS via operation of one to three (or more) stations in tool 140. At 640, the method 600 continues with the robot 112 being controlled by controller 104 based on recipe program 107 to retrieve the sample 500 from the front contact/window tool 140 via valve 144. Then, the robot 112 operates to move the sample 500 to PV thin film deposition tool 150 via valve 154. The tool 150 is operated to deposit, in a stepwise manner to avoid thermal shock (e.g., see FIGS. 3A to 3C), a thin film of CdTe 540. Next, the robot 112 may be operated to move the sample 500 to the post-deposition treatment tool 170 for treatment/annealing of the thin film 530 (e.g., with exposure to vapor CdCl₂ source 178 and/or by operating the tool 170 as a CSS tool with a CdCl₂ source). Then, at 660, the robot 112 is operated to move the sample 500 from the tool 170 into the dry contact tool 180, and the tool 180 is operated to sputter the back contact 550 shown as a ZnTe:Cu/Ti layer 550 on annealed CdTe layer 540. The robot 112 is then operated to unload the PV device/sample 500 from the cluster 100, and the method 600 ends at 690 (or is repeated for a next sample using the same or a different recipe).

The post-treatment of the CdTe thin film 530 with the tool 170 may be performed as described in U.S. Pat. No. 5,909,632, which is incorporated herein in its entirety by reference. For example, the tool 170 may be configured to provide dry processing using ion-beam milling to condition the CdTe surface. Additionally, the dry contact tool 180 may be configured to apply the back contact in a dry manner including sputtering of ZnTe using the techniques described in the U.S. Pat. No. 5,909,632, e.g., at least one of the sputtering stations in the tool 180 may be configured to deposit ZnTe layers as taught in this patent that is incorporated herein. In other cases, the tools 170 and 180 may be operated/configured as taught in U.S. Pat. Nos. 6,281,035 and/or 6,458,254, which are each incorporated herein by reference in their entireties, to provide dry post-deposition treatment as well as dry application of a back contact on a PV device.

Application of the TCO layer and/or the application of the front contact/window layer may be performed as taught in U.S. Pat. No. 5,922,142, which is incorporated herein in its entirety by reference (e.g., tool 120 may be adapted to apply a TCO film comprising cadmium stannate or the like and tool 140 may be adapted to apply at least a layer of cadmium sulfide to provide the front contact/window of a PV device). Alternatively (or in some combination), the layers 520, 530 may be applied by operating the tool 120 and/or tool 140 as taught in U.S. Pat. Nos. 6,137,048; 6,169,246; and/or 6,221,495 and/or as taught in U.S. Pat. Appl. Publ. No. 2005/0009228, which are each incorporated herein by reference in their entireties.

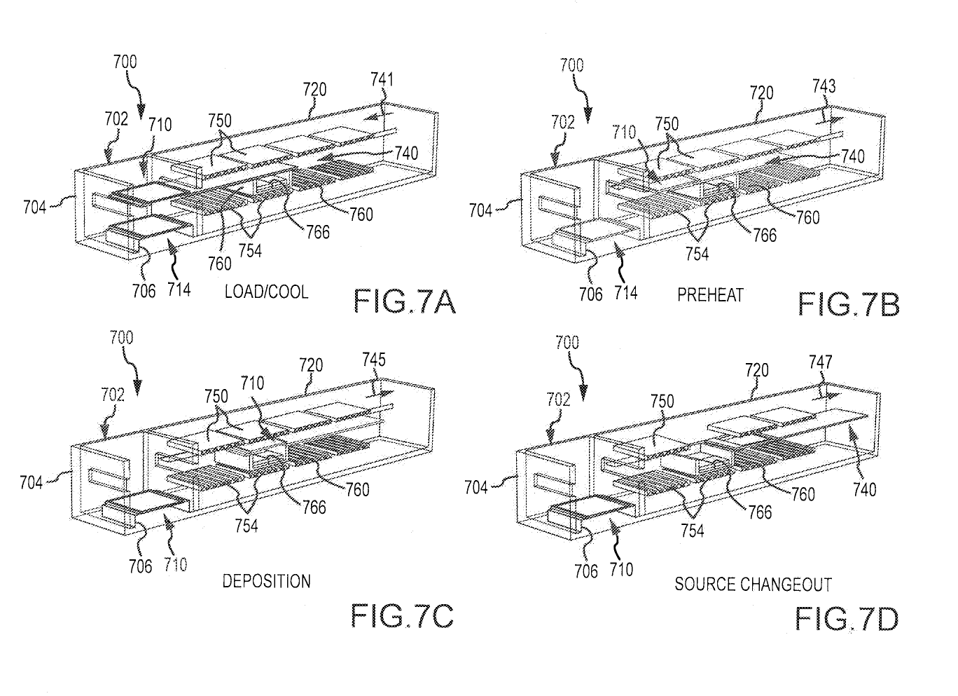

FIGS. 7A to 7D illustrate a perspective view of a thin film deposition/processing tool 700 as may be used in a cluster assembly described herein (such as for tool 150 or 170 of cluster tool 100 of FIG. 1). The tool 700 is shown in simplified form (e.g., with some components left out for simplification of illustration and explanation of key components) and with the top/cover and front wall/side removed. The tool 700 includes a load/unload assembly 702 with a chamber 704 for receiving a sample 710 and a lift (not shown) may be used to position a second (or additional) samples 714 on a cooling rack/station such as after application of a layer of material via source 766 (e.g., after application of a CdTe thin film). The tool 700 further includes a deposition chamber 720, an integral shutter 740 for covering an opening to a source material 766 and positioning the sample 710, and also a set of top heaters 760 and bottom heaters 754 (e.g., IR heaters). A source boat/holder 760 is provided between the top and bottom heaters 750, 754 such as between a second pair of such heaters relative to the load/unload chamber 704.

FIG. 7A illustrates the tool 700 in a load/cool mode of operation. In this configuration, the integral shutter 740 is moved 741 outward such that its fork receives a new sample 710 (e.g., from a central sample transfer robot or the like). A previously processed sample 714 is positioned on cooling rack 706 (such as by a lift (not shown)), where it may be cooled for a period of time prior to removal by a robot arm or other movement mechanism (e.g., for further processing such as post-deposition and annealing of a CdTe thin film or application of a back contact or the like). In some cases, the substrate 710 may be heated with an additional heater(s) (not shown). As shown, the stage 702 contains a two sample cassette so that a warm sample may be introduced on top and a hot sample may be cooled after deposition.

FIG. 7B illustrates the tool in a preheat mode of operation. In this configuration, the integral shutter 740 is moved inward as shown at 743 such that the substrate/sample 710 is picked up by the hot shutter (heated to a desired temperature by heaters 750, 754 to temperature up to about 300° C. or more). The sample 710 may be heated as shown in FIG. 7B by first pairs of top and bottom heaters 750, 754 to a preheat temperature of up to about 450° C. while the shutter temperature (or its body) may be increased to 450 to 500° C. or the like. The zone between these first two heaters 750, 754 nearest load/unload chamber 704 may be maintained at 450° C. for cooling/unload (e.g., to avoid thermal shock of 50° C. or more by the sample 710). During both load/cool in FIG. 7A and preheating in FIG. 7B, the body of the integral shutter is used to cover the source material 766 (or the opening to boat/source holder 760) such that deposition material is not released into the chamber 720.

After preheating is complete, deposition may proceed as shown in FIG. 7C. In this step, the integral shutter 740 is drawn further as shown at 745 into the chamber 720 such that its planar body is moved away from the boat/holder 760 such that the deposition material/source 766 is exposed. The fork of the shutter 740 with the sample 710 is moved over the deposition material/source 766 and the sample surfaces are covered with a thin film or otherwise processed by the source 766. The shutter 740 is adapted such that the material only does not leak past the sides of the fork and/or sample 710 or its carrier. After deposition as show in FIG. 7C, the sample 710 may be moved out into the unload/load chamber 704 and cooled as shown in FIG. 7D (also, active cooling may be provided by one or more cooling components (not shown) in load/unload chamber 704 near cooling rack/station 706). Cooling may be desirable since the robotic hardware may have temperature handling limits (such as less than about 400° C. or the like) and cooling may be used to support the robot limitations (as the next processing step may be a CdCl2 process that may desire high temperatures such as 400° C. or above). The source 766 may be a CSS CdTe source and it may be maintained at 500° C. during idle/dormancy and then during deposition it may be heated further by a bottom heater 754 to at least about 650° C. while the substrate/sample 710 may be heated to 500 to 600° C. by a top heater 750. The integral shutter 740 may then be fully retracted to move the body and fork of the shutter 740 away from the source 766 and a heater 750 removed to allow source change out.

While a number of exemplary aspects and embodiments have been discussed above, those of skill in the art will recognize certain modifications, permutations, additions, and sub-combinations thereof. It is therefore intended that the following appended claims and claims hereafter introduced are interpreted to include modifications, permutations, additions, and sub-combinations to the exemplary aspects and embodiments discussed above as are within their true spirit and scope.

For example, in some cases of the CSS tool using the integrated shutter, the source material is provided in a boat that may be “plug and play” to allow ready replacement of sources. Many of the CSS tool components may be formed of graphite such as the source boat, the integrated shutter, and the carrier for the samples/substrates (or the carrier may be formed of molybdenum or the like). The shutter and carrier are preferably configured to provide/maintain a desired distance between a source and the sample surface (e.g., a sublimation distance) such as between about 1 and 15 mm or the like depending on the source and the deposition pressure (e.g., 1-10 s of ton while some embodiments may operate in the mtorr range to reduce particle formation in the chamber and thermal loads). The shutter body typically moves in a single plane (e.g., no vertical movement) and, in this regard, the heater locations (such as the IR heaters on the top/bottom of a chamber) are typically fixed. Likewise, the source temperatures may vary significantly to practice cluster assemblies, and embodiments may allow for source temperatures up to about 800° C. (as measured in the bottom of the source material boat) and substrate/shutter temperatures may be closer to about 650° C.

In some embodiments, the integral shutter is modified to include an enclosed frame or loop structure extending outward from the body in place of open forks. Then, jacking rails may be provided in the load/unload chamber to raise up a received carrier/sample, allow the frame or loop (which may take the shape of a typical picture frame such as a square or rectangle with elongate side members or walls defining an open square or rectangular space) to be moved into the load/unload chamber, and then use the jacking rails to lower the carrier onto this end loop or frame member. In this manner, the integral shutter may completely surround the carrier on all four sides with a protection lip so as to limit CdTe vapor condensation on the carrier (or other escape of the source material from the front, open end of a fork). In this way, the integral shutter may be viewed as a source shutter with a hole that accepts the substrate plus the carrier, and the shutter provides a mechanism to move (isothermally) the substrate from a preheat position over the source in such a way as to limit the possibility of homogenous nucleation. The jacking rails or another lift mechanism provide a handoff with a robot in the sample transfer chamber or load/unload chamber of a particular module or tool.

It is often useful that temperatures of all regions/parts of the shutter are controllable so that the thermal environment of the CdTe or other source is not perturbed as various parts of the shutter are positioned over the source during differing steps or parts of the CSS process sequence (e.g., desirable in many cases for the portion of the shutter over the opening to the source material be the same or nearly the same as the source material (e.g., with 50° C. or more typically within about 10° C. or even within 2 to 3° C.). The shutter body may be generally planar and have a relatively small thickness (e.g., 0.2 to 0.5 inches thick) and may be formed of graphite or a similar material that is useful in deposition environments (e.g., to limit differential expansion and reaction).

The front and back contact application tools/modules may have a chamber with four sputter chambers (divided by shielding). Each chamber may have adjustable position sputter sources. A first source may be a linear ion source and/or provide ion etching. A second source may provide contact interface sputtering. The third and fourth sources/chambers may be used for providing first and second metal sputtering. The dry contact tool provided for creating the back contact may include a chamber configured to perform the following four steps: (a) etching of approximately 1000 A CdTe (e.g., by ion beam milling, by inert-gas plasma etch, or the like; (b) ZnTe back contact deposition (5000 A); (c) a first back contact metallization (˜1 mm); and (d) a second back contact metallization (not used in all devices, though). The dry contact tool may also be configured to provide the capability for ion-beam milling CdTe at a rate of 2-3 A/s to remove about 1000 Angstroms (e.g., with Linear Kaufmann source, with inert-gas ions, or the like). The chamber of this tool may also be configured to provide a ZnTe deposition rate of 5-6 A/s (RF or pulsed DC) and also provide a metal deposition rate of 10-12 A/s (DC). To this end, the chamber may include large linear cathodes.

Throughout the above description and the following claims, it should be understood that the terms superstrate and substrate were both used, and the samples and devices described herein may include either a superstrate or a substrate (with substrate often being used loosely to also include superstrate devices). Additionally, while glass superstrates and substrates were used in many of the examples, the concepts taught herein are clearly not limited to use of only glass for the substrates and superstrates as samples/devices may utilize metal foils and other substrates. Additionally, the cluster tools and assemblies are not limited to the “deposit up” configuration, as one or more of the modules or tools may be configured for deposit down (or a combination of deposit up and down). Further, the figures and description referred to a “front-contact/window layer” chamber or tool. In practice, the TCO or TCO/buffer stack is the front contact of a sample or PV device. The CdS material or layer is the window layer. In some implementations, the cluster assembly or tool may be configured to sputter all of these layers in the first sputter chamber or the TCO could be grown by CVD.

1. A thin film deposition apparatus, comprising:
a deposition chamber operable at vacuum;
a source container for containing deposition material and including an outlet into the deposition chamber; and
a shutter assembly including a planar shutter body and a sample carrier receiver extending from an end of the shutter body, wherein the carrier receiver is configured for receiving a sample carrier and includes an opening for exposing a surface of a sample positioned in the received sample carrier and wherein the shutter assembly is selectively positionable within the deposition chamber to first cover the outlet of the source container with the shutter body and to a second position in the received sample carrier over the outlet of the source container with the sample surface exposed to the deposition material through the opening in the carrier receiver.

2. The apparatus of claim 1, further comprising a preheat station in the deposition chamber adjacent the source container, wherein the shutter assembly is configured for concurrently positioning the received sample carrier in the preheat station during the first positioning with the shutter body covering the outlet of the source container.

3. The apparatus of claim 2, further comprising a source heater for heating the deposition material in the source container to a deposition temperature and wherein the preheat station comprises at least one heater for, during the first positioning, heating the sample in the sample carrier to a preheat temperature within about 50° C. of the deposition temperature.

4. The apparatus of claim 3, wherein the sample comprises a substrate or superstrate formed of a material selected from the group consisting of glass, metal, polymer, and ceramic, wherein the deposition material comprises cadmium telluride, and wherein the deposition temperature is at least about 500° C.

5. The apparatus of claim 1, further comprising at least one shutter heater positioned in the deposition chamber and operable to heat the shutter body to a temperature of at least about a temperature of the source container.

6. The apparatus of claim 5, wherein the sample carrier receiver comprises sidewalls forming a receiving surface for the sample carrier and defining the opening for exposing the surface of the sample and wherein the sidewalls are positioned proximate to an upper edge of the source container during the second positioning of the shutter assembly.

7. The apparatus of claim 1, further comprising a load and unload chamber connected to the deposition chamber via an access valve, wherein the load and unload chamber is configured for receiving the sample carrier and preheating the sample to an initial preheat temperature and wherein the shutter assembly is selectively positionable with the sample carrier receiver within the load and unload chamber to retrieve the sample carrier, the shutter body extending over the outlet of the source container during the retrieval of the sample carrier.

8. A deposition cluster assembly for use in fabricating a device with a thin film of cadmium telluride (CdTe) or other material on a substrate, comprising:
a sample transfer chamber maintained under vacuum;
a post-deposition tool connected to the sample transfer chamber, the post-deposition tool comprising a chamber for selectively exposing the thin, film on the substrate to vapor cadmium chloride when the device is transferred from the sample transfer chamber to the dry post-deposition tool; and
a dry contact tool connected to the sample transfer chamber, the dry contact tool comprising a chamber containing one or more components for sputtering a back contact onto the thin film.

9. The assembly of claim 8, wherein the thin film comprises CdTe.

10. The assembly of claim 8, further comprising a close spaced sublimation (CSS) tool connected to the sample transfer chamber, the CSS tool comprising a chamber with a preheater and a CdTe source and an integral shutter with a planar body and a carrier receiver, wherein the integral shutter is configured for selectively positioning the carrier receiver near the preheater to preheat the device positioned in a carrier while the planar body covers an opening to the CdTe source and then positioning the carrier receiver over the opening to the CdTe so as to expose the substrate of the device to the CdTe source.

11. The assembly of claim 10, wherein the dry post-deposition tool chamber comprises a source container and a preheater adjacent the source container and further comprises an integral shutter with a planar body and a carrier receiver, the integral shutter being configured for selectively positioning the carrier receiver near, the preheater to preheat the device positioned in the carrier while the planar body covers an opening to the source container and then positioning the carrier receiver over the opening to the source container so as to expose the thin film deposited by the CSS tool to the vapor cadmium chloride.

12. The assembly of claim 11, wherein the temperature of the substrate of the device is heated in the CSS tool preheater and the dry post-deposition tool preheater to temperatures within at least about 50° C. of a temperature of the CdTe source and a temperature of the source container, respectively.

13. The assembly of claim 8, further comprising an additional processing tool comprising a chamber connected to the sample transfer chamber configured for dry processing of the substrate of the device to sputter on a front contact layer onto a surface of the substrate.

14. The assembly of claim 8, further comprising mechanisms for providing thermal management of the device in the cluster assembly, whereby thermal shock experienced by the substrate of the device is less than about 50° C. in the assembly.

15. The assembly of claim 8, wherein the sample transfer chamber comprises a sample transfer robot operable to move the device in a carrier from the dry post-deposition tool to the dry contact tool.

16. A deposition cluster tool for non-wet chemical processing of a sample or device such as a photovoltaic, thin film device, comprising:
a sample transfer chamber maintained at vacuum and containing a sample transfer robot for selectively positioning a carrier containing a sample including a substrate;
a first tool comprising a chamber accessible via the sample transfer chamber, wherein the first tool comprises at least one sputtering component in the chamber for sputtering a front contact onto the substrate;
a second tool comprising a close spaced sublimation chamber accessible via the sample transfer chamber, wherein the second tool comprises a deposition source and a shutter with a planar body and a carrier receiver for receiving the carrier and wherein the shutter is selectively positionable in the chamber to position the planar body over an opening to the deposition source and to position the carrier receiver over the opening to expose the front contact layer to the deposition source, whereby a thin film is deposited upon the front contact layer; and
a third tool comprising a close spaced sublimation chamber accessible via the sample transfer chamber, wherein the third tool comprises a post-deposition processing source and a shutter with a planar body and a carrier receiver for receiving the carrier and wherein the shutter is selectively positionable in the chamber to position the planar body over an opening to the post-deposition processing source and to position the carrier receiver over the opening to expose the thin film to the post-deposition processing source.

17. The tool of claim 16, wherein the deposition source contains a CdTe source maintained at a temperature at or above a dormancy temperature of 500° C. and wherein the post-deposition processing source contains a CdCl₂ source.

18. The tool of claim 17, wherein the CSS chamber of the second tool further comprises a preheat station operable to heat the substrate to a preheat temperature of at least about 300° C. while the planar body of the second tool shutter is over the opening to the CdTe source.

19. The tool of claim 16, further comprising a fourth tool comprising a chamber accessible via the sample transfer chamber, wherein the first tool comprises at least one sputtering component for sputtering a back contact onto the thin film.

20. The tool of claim 16, further comprising a fifth tool comprising a chamber accessible via the sample transfer chamber, the chamber configured for chemical vapor deposition of a transparent conducting oxide layer on the substrate prior to sputtering of the front contact by the first tool.

21. The tool of claim 20, wherein the substrate is a glass substrate or glass superstrate and the tool further comprises thermal management mechanisms operable to maintain a temperature of the glass substrate within about 50° C. of a next process in the tool, whereby a transfer temperature is maintained throughout the tool.
